(19) United States
(12) Patent Application Publication
(10) Pub. No.: US 2021/0184480 A1
(43) Pub. Date: Jun. 17, 2021

(54) CHARGE/DISCHARGE CONTROL DEVICE AND BATTERY APPARATUS

(71) Applicant: ABLIC Inc., Tokyo (JP)

(72) Inventor: Fumihiko Maetani, Tokyo (JP)

(21) Appl. No.: 17/111,920

(22) Filed: Dec. 4, 2020

(30) Foreign Application Priority Data
Dec. 17, 2019 (JP) 2019-227616

(51) Int. Cl. H02J 7/00

(52) U.S. Cl. CPC H02J 7/0048; H02J 7/00712; H02J 7/0071

(57) ABSTRACT

A charge/discharge control device and a battery apparatus which are compatible with a quick-chargeable charging device which changes a charging current stepwise, the charge/discharge control device and a battery apparatus include an alarm output circuit connected to a control circuit, and a timer circuit which counts a preset period according to an output of an alarm signal from the alarm output circuit and supplies a signal which inhibits the charging to the control circuit after counting the preset period.

### RELATED APPLICATIONS

This application claims priority to Japanese Patent Application No. 2019-227616, filed Dec. 17, 2019, the entire content of which is incorporated herein by reference.

### BACKGROUND OF THE INVENTION

### 1. Field of the Invention

The present invention relates to a charge/discharge control device and a battery apparatus.

### 2. Description of the Related Art

FIG. 3 illustrates a block diagram of a conventional battery apparatus. The conventional battery apparatus 20 includes a battery 1, a discharge control FET 3, a charge control FET 4, a charge/discharge control device 21, external terminals EB+ and EB−, and an external terminal ALM. The charge/discharge control device 21 includes a voltage detection circuit 210, a control circuit 211, power supply terminals T1 and T2, FET control terminals T3 and T4, and an alarm output terminal T5.

The battery apparatus 20 does not supply an alarm signal while the voltage of the battery 1 is normal and lower than the overcharge voltage. Connection of a charging device 5 to the external terminals EB+ and EB− of the battery apparatus 20 starts charging at the maximum current in the absence of the alarm signal input to the charging device. The voltage of the battery 1 above the overcharge voltage causes the battery apparatus 20 to supply the alarm signal from the external terminal ALM. By the input of the alarm signal, the charging device 5 gradually reduces the charging current and continues charging.

The battery apparatus 20 constituted as described above is capable of quick and safe charging of the battery up to a voltage close to the full capacity with a simple circuit configuration (refer to, for example, Japanese Patent Application Laid-Open No. 2010-141987).

In the conventional battery apparatus, however, at an occurrence of anomalous situation in the charging device 5 which has started charging at the maximum current, a condition comes up in which the charging device 5 continues charging at the maximum current in spite of high voltage of the battery 1 even though the battery apparatus 20 supplies the alarm signal. A dangerous state may occur in which the charging at high current is performed in the vicinity of the maximum voltage of the battery voltage.

### SUMMARY OF THE INVENTION

The present invention provides a charge/discharge control device and a battery apparatus which, even if an anomalous situation occurs in the charging device 5 having started charging at the maximum current, securely prevents the battery 1 from reaching above the overcharge voltage and provides high safety.

According to one aspect of the present invention, a charge/discharge control device includes: a first power supply terminal to which one end of a battery is connected, and a second power supply terminal to which the other end of the battery and a source of a discharge control FET are connected; a discharge control terminal to which a gate of the discharge control FET is connected, and a charge control terminal to which a gate of a charge control FET is connected; a voltage detection circuit having a first input terminal connected to the first power supply terminal, and a second input terminal connected to the second power supply terminal; a control circuit having a first input terminal connected to an output terminal of the voltage detection circuit, a discharge FET control terminal connected to the discharge control terminal, and a charge FET control terminal connected to the charge control terminal; an alarm output circuit having an input terminal connected to an output terminal of the control circuit; an alarm output terminal to which a first output terminal of the alarm output circuit is connected; and a timer circuit having an input terminal connected to a second output terminal of the alarm output circuit, and an output terminal connected to a second input terminal of the control circuit, in which the alarm output circuit makes an output of an alarm signal from the alarm output terminal according to a detection of a voltage between the first input terminal and the second input terminal above an alarm signal output voltage by the voltage detection circuit, and in which the timer circuit counts a preset period according to the output of the alarm signal and sends an anomaly detection signal from the output terminal to the control circuit to stop charging after counting the preset period.

According to the present invention, there can be provided a charge/discharge control device and a battery apparatus which securely prevent high current charging in the vicinity of the maximum voltage of a battery and provide high safety even if an anomalous operation of a charging device takes place since a timer circuit which monitors a time for supplying an alarm signal from an alarm output circuit is provided.

### BRIEF DESCRIPTION OF THE DRAWINGS

FIG. 1 is a block diagram illustrating a battery apparatus according to an embodiment of the present invention;

FIG. 2 is a block diagram illustrating another example of the battery apparatus according to an embodiment of the present invention; and

FIG. 3 is a block diagram illustrating a conventional battery apparatus.

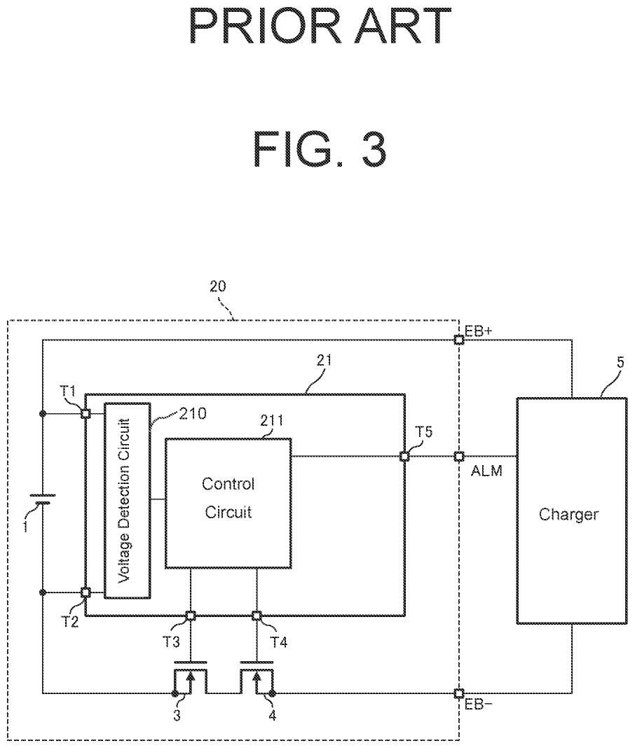

### DETAILED DESCRIPTION OF THE PREFERRED EMBODIMENTS

Embodiments of the present invention will hereinafter be described with reference to the accompanying drawings.

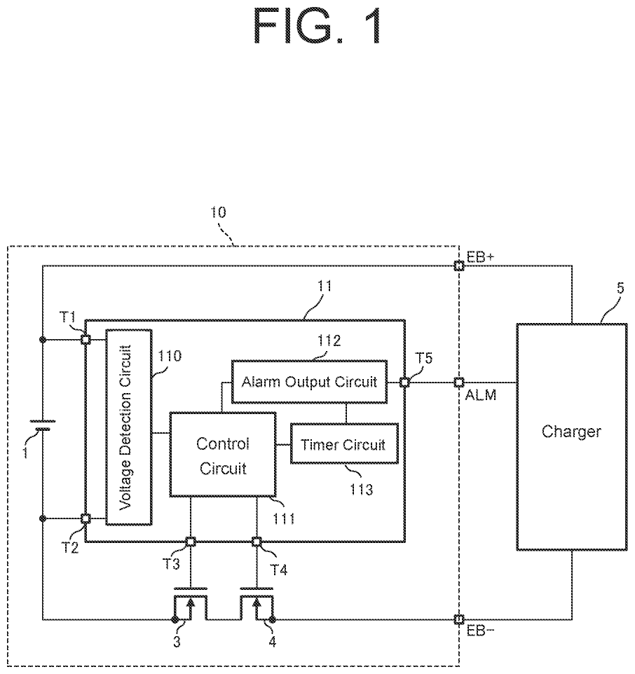

FIG. 1 is a block diagram illustrating a battery apparatus 10 according to the embodiment of the present invention. The battery apparatus 10 includes a battery 1, a discharge control FET 3, a charge control FET 4, a charge/discharge control device 11, external terminals EB+ and EB−, and an external terminal ALM.

The battery 1 has a positive terminal connected to the external terminal EB+. The charge/discharge control device 11 has a power supply terminal T1 connected to the positive terminal of the battery 1, a power supply terminal T2 connected to a negative terminal of the battery 1, an FET control terminal T3 connected to a gate terminal of the discharge control FET 3, an FET control terminal T4 connected to a gate terminal of the charge control FET 4, and an alarm output terminal T5 connected to the external terminal ALM. The discharge control FET 3 has a source terminal connected to the negative terminal of the battery 1 and a drain terminal connected to a drain terminal of the charge control PET 4. A source terminal of the charge control PET 4 is connected to the external terminal EB−.

The charge/discharge control device 11 includes a voltage detection circuit 110, a control circuit 111, an alarm output circuit 112, a timer circuit 113, power supply terminals T1 and T2, FET control terminals T3 and T4, and an alarm output terminal T5. The voltage detection circuit 110 has a first input terminal connected to the power supply terminal T1, a second input terminal connected to the power supply terminal T2, and an output terminal connected to a first input terminal of the control circuit 111. The control circuit 111 has an output terminal connected to an input terminal of the alarm output circuit 112, a second input terminal connected to an output terminal of the timer circuit 113, a discharge control terminal connected to the FET control terminal T3, and a charge control terminal connected to the FET control terminal T4. The alarm output circuit 112 has a first output terminal connected to the alarm output terminal T5, and a second output terminal connected to an input terminal of the timer circuit 113. The output terminal of the timer circuit 113 is connected to the second input terminal of the control circuit 111.

The operation of the battery apparatus 10 constituted as described above will next be described. Here the voltages detected by the control circuit 111 include an overcharge voltage, an alarm signal output voltage, and an overdischarge voltage among which the magnitudes are assumed to be overcharge voltage>alarm signal output voltage>overdischarge voltage.

The voltage detection circuit 110 monitors the voltage of the battery 1 supplied from the power supply terminals T1 and T2 and sends a signal corresponding to the voltage to the control circuit 111. The control circuit 111 sends signals from the FET control terminals T3 and T4 according to the signal provided from the voltage detection circuit 110 to turn ON and OFF the discharge control FET 3 and the charge control FET 4.

Connection of a charging device 5 between the external terminals EB+ and EB− of the battery apparatus 10 starts the charging of the battery 1 by the charging device 5. At this time, while the voltage of the battery 1 is above the overdischarge voltage and lower than the alarm signal output voltage, the control circuit 111 sends a signal which inhibits the output of an alarm signal from the output terminal to the input terminal of the alarm output circuit 112. In an initial state in which no alarm signal is supplied from the battery apparatus 10, the charging device 5 starts charging of the battery 1 at the maximum charging current. That is, quick charging is made to the battery 1.

At the detection of the voltage of the battery 1 being higher than or equal to the alarm signal output voltage, the voltage detection circuit 110 sends a detection signal from the output terminal to the first input terminal of the control circuit 111. By the input of the detection signal from the voltage detection circuit 110, the control circuit 111 sends a signal which permits the output of the alarm signal from the output terminal to the input terminal of the alarm output circuit 112. The alarm output circuit 112 sends the alarm signal from the output terminal to the charging device 5 through the external terminal ALM. By the input of the alarm signal from the battery apparatus 10 during charging, the charging device 5 reduces the charging current one step. Since the reduction of the charging current causes lowering of the voltage of the battery 1 to a voltage under the alarm signal output voltage, the voltage detection circuit 110 stops the supply of the detection signal. Then, the alarm output circuit 112 stops the alarm signal to the charging device 5. The battery apparatus 10 repeats the charging, the supply of the alarm signal, the reduction of the charging current, and the stop of the alarm signal and thereby carries out quick and safe charging of the battery 1.

Here, the timer circuit 113 counts a preset period while the input terminal thereof is supplied with a signal indicating the output of the alarm signal from the alarm output circuit 112 and stops counting by the stop of the alarm signal, initializing the counting state. Then, the timer circuit 113 sends an anomaly detection signal from the output terminal to the second input terminal of the control circuit 111 after counting the preset period. The preset period counted by the timer circuit 113 is set longer than the time required to supply the alarm signal from the alarm output circuit 112, reduce the charging current one step by the charging device 5, and detect the decrease in the voltage of the battery 1 by the voltage detection circuit 110.

By the input of the anomaly detection signal from the timer circuit 113 to the second input terminal of the control circuit 111, regardless of an overcharge state of the output signal from the voltage detection circuit 110, the control circuit 111 supplies a signal from the FET control terminal T4 to turn OFF the charge control FET 4 and stops charging. Even if an anomaly occurs, for example, in the operation of the charging device 5 having started quick charging of the battery 1 with the maximum charging current, the charge control FET 4 can be turned OFF accordingly to stop the charging regardless of the overcharge state of the output signal of the voltage detection circuit 110.

As described above, according to the embodiment, there can be provided a highly safe charge/discharge control device and a battery apparatus which are compatible with a quick-chargeable charging device allowing stepwise change of the charging current.

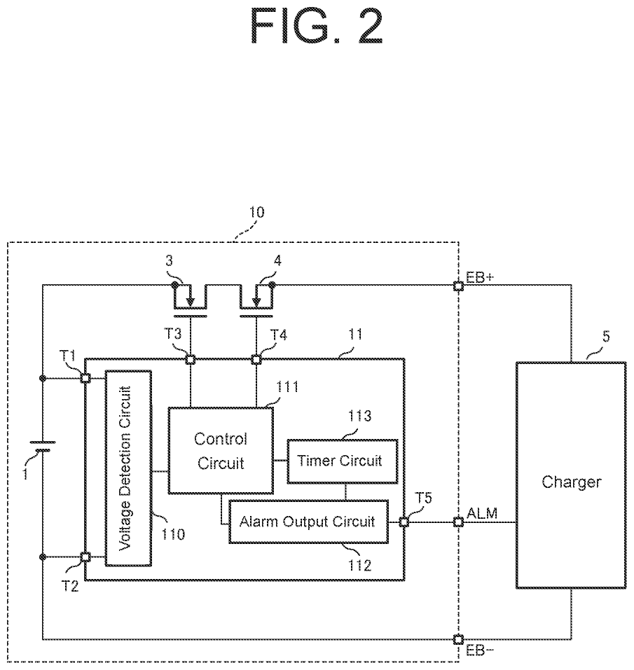

FIG. 2 is a block diagram illustrating another example of the battery apparatus according to the embodiment. Even if a high-side charge/discharge control is carried out as in the battery apparatus 10 of FIG. 2, the present invention can be applied in the same manner.

Although the embodiments of the present invention have been described above, the present invention is not limited to the above embodiments. Various changes can be made thereto within the scope not departing from the spirit of the present invention.

For example, in the embodiments described above, the alarm signal itself may be used as the signal indicating the output of the alarm signal supplied from the alarm output circuit 112 to the timer circuit 113. Further, for example, in the embodiment, although the alarm signal output voltage is not provided with a release voltage, hysteresis may be provided in the alarm signal output voltage, i.e., an alarm signal release voltage may be provided.

What is claimed is:

1. A charge/discharge control device comprising:
a first power supply terminal to which one end of a battery is connected, and a second power supply terminal to which the other end of the battery and a source of a discharge control FET are connected;
a discharge control terminal to which a gate of the discharge control FET is connected, and a charge control terminal to which a gate of a charge control FET is connected;
a voltage detection circuit having a first input terminal connected to the first power supply terminal, and a second input terminal connected to the second power supply terminal;
a control circuit having a first input terminal connected to an output terminal of the voltage detection circuit, a discharge FET control terminal connected to the discharge control terminal, and a charge FET control terminal connected to the charge control terminal;
an alarm output circuit having an input terminal connected to an output terminal of the control circuit;
an alarm output terminal to which a first output terminal of the alarm output circuit is connected; and
a timer circuit having an input terminal connected to a second output terminal of the alarm output circuit, and an output terminal connected to a second input terminal of the control circuit,
wherein the alarm output circuit makes an output of an alarm signal from the alarm output terminal according to a detection of a voltage between the first input terminal and the second input terminal above an alarm signal output voltage by the voltage detection circuit, and
wherein the timer circuit counts a preset period according to the output of the alarm signal and sends an anomaly detection signal from the output terminal to the control circuit to stop charging after counting the preset period.

2. The charge/discharge control device according to claim 1, wherein the alarm output circuit sends the alarm signal from the alarm output terminal by an input of a signal which permits an output of the alarm signal to be supplied from the control circuit.

3. The charge/discharge control device according to claim 2, wherein the control circuit supplies a signal which permits an output of the alarm signal by an input of a detection signal indicative of the detection of the voltage between the first input terminal and the second input terminal being above the alarm signal output voltage from the voltage detection circuit to the first input terminal.

4. The charge/discharge control device according to claim 1, wherein the voltage detection circuit has an alarm signal release voltage lower than the alarm signal output voltage.

5. The charge/discharge control device according to claim 2, wherein the voltage detection circuit has an alarm signal release voltage lower than the alarm signal output voltage.

6. The charge/discharge control device according to claim 3, wherein the voltage detection circuit has an alarm signal release voltage lower than the alarm signal output voltage.

7. A battery apparatus comprising:
a battery;
a first external terminal connected to one end of the battery;
a second external terminal;
a discharge control FET and a charge control FET provided between the other end of the battery and the second external terminal and having drains connected to each other;
the charge/discharge control device according to claim 1; and
a third external terminal connected to the alarm output terminal of the charge/discharge control device.

8. A battery apparatus comprising:
a battery;
a first external terminal connected to one end of the battery;
a second external terminal;
a discharge control FET and a charge control FET provided between the other end of the battery and the second external terminal and having drains connected to each other;
the charge/discharge control device according to claim 2; and
a third external terminal connected to the alarm output terminal of the charge/discharge control device.

9. A battery apparatus comprising:
a battery;
a first external terminal connected to one end of the battery;
a second external terminal;
a discharge control FET and a charge control FET provided between the other end of the battery and the second external terminal and having drains connected to each other;
the charge/discharge control device according to claim 3; and
a third external terminal connected to the alarm output terminal of the charge/discharge control device.

10. A battery apparatus comprising:
a battery;
a first external terminal connected to one end of the battery;
a second external terminal;
a discharge control FET and a charge control FET provided between the other end of the battery and the second external terminal and having drains connected to each other;
the charge/discharge control device according to claim 4; and
a third external terminal connected to the alarm output terminal of the charge/discharge control device.

11. A battery apparatus comprising:
a battery;
a first external terminal connected to one end of the battery;
a second external terminal;
a discharge control FET and a charge control FET provided between the other end of the battery and the second external terminal and having drains connected to each other;
the charge/discharge control device according to claim 5; and
a third external terminal connected to the alarm output terminal of the charge/discharge control device.

12. A battery apparatus comprising:
a battery;
a first external terminal connected to one end of the battery;
a second external terminal;
a discharge control FET and a charge control FET provided between the other end of the battery and the second external terminal and having drains connected to each other;
the charge/discharge control device according to claim 6; and
a third external terminal connected to the alarm output terminal of the charge/discharge control device.
